(19) United States
(12) Patent Application Publication
(10) Pub. No.: US 2008/0160787 A1
(43) Pub. Date: Jul. 3, 2008

(54) Method For Manufacturing a Thin-Layer Structure

(75) Inventor: Volker Lehmann, Muenchen (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: QIMONDA AG, Muenchen (DE)

(21) Appl. No.: 11/817,474

(22) PCT Filed: Feb. 13, 2006
(86) PCT No.: PCT/EP06/00248

§ 371 Date: Aug. 30, 2007

(30) Foreign Application Priority Data
Mar. 3, 2005 (DE) 10 2005 010 080.5
Feb. 13, 2006 (DE) PCT/DE2006/000248

(51) Int. Cl. H01L 21/31

(52) U.S. Cl. 438/791; 257/E21.24

(57) ABSTRACT

A method for manufacturing a thin-layer structure is disclosed. In one embodiment a macroporous supporting structure substrate having a plurality of pores that do not pass through the entire thickness of the substrate layer, a sacrificial layer is applied on the surface of the pore walls and the pore bottoms of the supporting structure substrate. The supporting structure substrate is partly removed on the rear side, such that a region of the sacrificial layer is uncovered on the rear side of the supporting structure substrate. A thin layer is applied on the rear side surface of the supporting structure substrate and also on the uncovered region of the sacrificial layer. The sacrificial layer in the pores is removed selectively with respect to the thin layer, such that the pore bottoms are formed by the thin layer.

### TECHNICAL FIELD

The present invention relates to a device and a method for preparing hot chocolate milk comprising an agitator and having a chocolate product attached thereto, whereby the chocolate product can be dissolved in hot milk when introduced herein, thereby forming hot chocolate milk. In addition, the present invention also provides a method for preparing hot chocolate milk.

### BACKGROUND

Existing devices for preparing chocolate milk generally comprise a chocolate product, which is added to hot milk in such a quantity until a suitable discoloration is apparent. This discoloration corresponds to a desired taste, which is individually determined.

In general cacao powders that have improved solubility compared to traditional chocolate are available on the market. The composition of such powders is however such that the original taste of cacao or chocolate is generally lost. Therefore, this kind of products is less desired on the market.

It is more and more a trend to prepare chocolate milk starting from chocolate that is provided in small pastilles or in chocolate bars. The chocolate product may be provided in a package. However, a problem associated with this type of chocolate products is that the chocolate is of such composition that it easily becomes sticky and at least partly melts in its package, such that a substantial amount of product is lost. Omitting package of the chocolate product in order to avoiding such problems on the other hand has the disadvantage that the chocolate product will easily dry out, loose flavour and show a seriously reduced durability. Another important problem associated with this type of chocolate products is that they have a composition, which does not exhibit a desired melting capacity. The chocolate does not sufficiently dissolve in a liquid and as a consequence thereof, generally chocolate remains and/or it is difficult to correctly dose the necessary chocolate.

The present invention aims to provide a suitable solution for at least some of the above-mentioned problems. More in particular, it is an object of the present invention to provide a device for preparing hot chocolate milk, which is suitable to prepare chocolate milk according to everybody's individual concentration and taste.

It is another object of the present invention to provide a device for preparing hot chocolate milk, comprising a chocolate product having an improved composition and improved properties.

The present invention also aims to provide in a simplified and quicker method for preparing chocolate milk.

### SUMMARY

The present invention relates to the provision of a convenient, stable, sanitary, device for preparing a hot beverage, adapted to be mixed with a liquid vehicle such as hot milk or other liquid to produce a beverage of the desired type and taste.

More specifically, the present invention provides in a first aspect a device for preparing hot chocolate milk, comprising an agitator having a chocolate product attached thereto, said chocolate product being suitable for being completely dissolved in hot milk, whereby the melting behavior of the chocolate product in the milk having a temperature of 70 to 90° C. is approximately 50 seconds. In the present description the term “melting behavior” is defined as the time which is required to dissolve the chocolate product in the hot milk, when slightly agitating the agitator in the milk. A preferred embodiment of the present invention is characterized in that the melting behavior of the chocolate product in milk having a temperature of about 80° C. is approximately 50 seconds.

In an advantageous embodiment, the chocolate product according to the present invention comprises a filling which comprises: chocolate, cream, and/or oil and optionally additional filling agents, and a chocolate jacket. The chocolate jacket improves the firmness and consistency of the product, while the chocolate filling consists of a well-defined mixture of chocolate and cream and/or oil so as to provide the desired melting behavior. The filling may consist of a mixture of chocolate with cream or with oil, or a combination hereof. Mixtures with oil float, while mixtures with cream may sediment. It will be clear that the filling comprises a mixture of chocolate of superior quality and a convenient type of cream and/or oil so as to provide the optimal melting behavior. Moreover, the present filling contributes to a softer feeling in the mouth and a better transfer of the taste.

In another embodiment the present invention provides a device, characterized in that the chocolate product is provided with a wrapper that is adapted for at least partly wrapping the chocolate product. The wrapper may be removed or not prior to immersion of the chocolate product in the hot milk. The wrapper serves to secure the chocolate product to the agitator or to prevent the chocolate product from falling off or being knocked off prior to the device being utilized to produce the hot chocolate. In addition, the wrapper is particularly suitable for enabling a user to pick up and hygienically hold the device according to the present invention by the chocolate product without touching the chocolate product. As such, the chocolate product does not melt between the fingers of a user, and no substantial chocolate product is lost before inserting the product into the hot milk. In addition, the wrapper also severs to improve the shelf life and the durability of the chocolate product and provides protection against melting of the chocolate product when the device according to the present invention is positioned in the vicinity of a cup of hot milk. This wrapper may also be suitable as carrier for information and/or publicity and can comprise instructions for use.

In another embodiment, the present invention provides a device, which is provided in a vacuum packing. Therefore, the invention also relates to a vacuum packing containing a device according to the present invention. This packing may also be suitable as carrier for information and/or publicity and can comprise instructions for use.

In still another embodiment, the invention provides a method for preparing hot chocolate milk. The method comprises the steps of:
warming up milk to obtain hot milk of a temperature of about 70 to 90° C., preferably of about 80° C.,
bringing a device according to the invention into contact with said hot milk,
gently agitating the agitator of said device until a suitable discoloration becomes apparent, and
optionally removing a non-desired rest fraction of said device out of the milk.

In yet another embodiment the present invention provides a kit comprising a cup for containing chocolate milk and a dish adapted for positioning said cup, and a device according to the invention. The disk is adapted to position a cup as well as a device according to the invention next to each other. The dish is preferably oval. The chocolate cup is suitable as carrier for information and/or publicity and can be provided with a relief, which improves gripping of the cup and for instance serves as isolating handle of the cup. It shall be clear that the cup and the accompanying dish may exist in different colors, whereby the colors may provide an indication with regard to the taste to be expected of the chocolate milk.

Additional features and examples of present device according to the present invention will be discussed below in a non-limitative way with reference to the appending drawings.

### DESCRIPTION OF THE FIGURES

FIG. 1 represents a kit according to the present invention.

FIG. 2 illustrates a preferred embodiment of a frontal view of a device.

FIG. 3 illustrates the preferred device represented in FIG. 2 in an individual packing.

FIG. 4 shows a device according to the present invention d wherein the chocolate product is of a square form in transversal section.

FIG. 5 illustrates a wrapper that is adapted for at least partly wrapping the chocolate product of a device according to the invention.

FIG. 6 represents a preferred embodiment of device according to the present invention, wherein the device has been wrapped with a wrapper as represented in FIG. 5.

### DETAILED DESCRIPTION OF THE INVENTION

The present invention relates to a device for preparing hot chocolate milk, comprising an agitator having a chocolate product attached thereto. The chocolate product is in particular characterized in that it has a composition in order to be adapted to be completely dissolved in hot milk. In a preferred embodiment, the chocolate product is dispersed with normal agitation e.g. hand stirring with the agitator of the device or a spoon, within 50 seconds, and preferably within 45 seconds and preferably within 30 seconds in a cup of milk of 70 to 90° C., or within 50 seconds, and preferably within 45 seconds and preferably within 30 seconds in a cup of milk of 85° C., or within 50 seconds, and preferably within 45 seconds and preferably within 30 seconds in a cup of milk of 82.5° C., or within 50 seconds, and preferably within 45 seconds and preferably within 30 seconds in a cup of milk of 80° C.

In another preferred embodiment a chocolate product of between 10 to 40 gram, and preferably of between 25 and 35 gram, is dispersed with normal agitation e.g. hand stirring with the agitator of the device or a spoon, within 50 seconds, and preferably within 45 seconds and preferably within 30 seconds in a cup of milk of 15 to 150 ml and having a temperature of 70 to 90° C., or within 50 seconds, and preferably within 45 seconds and preferably within 30 seconds in a cup of milk of 15 to 150 ml and having a temperature of 85° C., within 50 seconds, and preferably within 45 seconds and preferably within 30 seconds in a cup of milk of 15 to 150 ml and having a temperature of 82.5° C., or within 50 seconds, and preferably within 45 seconds and preferably within 30 seconds in a cup of milk of 15 to 150 ml and having a temperature of 80° C.

In a preferred embodiment, the chocolate product comprises a filling and a chocolate jacket. Preferably the chocolate product comprises between 70 and 90% by weight, and preferably between 75 and 85% by weight of a filling, and between 10 and 30% by weight, and preferably between 15 and 25% by weight of a chocolate jacket.

In a further preferred embodiment, the filling comprises chocolate, cream and/or oil, and optionally other filling agents. Preferably the filling comprises between 60 and 90% by weight, and preferably between 70 and 85% by weight of chocolate; between 10 and 40% by weight, and preferably between 15 and 30% by weight of cream; between 0 and 30% by weight, and preferably between 0 and 15% by weight of oil; between 0 and 30% by weight, and preferably between 0 and 15% by weight of filling agents.

Preferably the filling agents are selected from the group comprising but not limited to components such as nuts, honey, tastemakers or flavors (natural or non natural); and components that are eventually based on alcohol such as for instance advocaat liquor, rum, cognac, fruit liquor or kirsh. These filling agents may for instance comprise components including but not limited to almond nut, amaraetto, anisette, brandy, cappuccino, mint, cinnamon, cinnamon almond, creme de menthe, grand mariner, peppermint stick, pistachio, sambuca, apple, camomile, cinnamon spice, creme, creme me de menthe, vanilla, french vanilla, Irish creme, kahlua, lemon, macadamia nut, orange, orange leaf, peach, strawberry, grape, raspberry, cherry, coffee, chocolate and the like, aroma enhancers such as acetaldehyde, herbs, spices, mocha, butternut, rum, hazelnut, horchata, dulche de leche, advocaat liquor, rum, cognac, fruit liquor, cointreau, or kirsh etc., as well as mixtures of these components.

In a preferred embodiment, the chocolate product comprises a filling in which the ratio of chocolate to cream is comprised between 4:1 and 1:4 and for instance between 3:1 and 1:3, and for instance is 1:1; 2:1 or 3:1. In yet another preferred embodiment, the chocolate product comprises a filling wherein the ratio of chocolate to oil is comprised between 12:1 en 5:1, and for instance comprises 10:1. In another preferred embodiment, the chocolate product comprises a filling wherein the ratio of chocolate to the other filling agents is comprised between 25:1 and 5:1, and for instance comprises 10:1.

In a preferred embodiment, the filling of the present chocolate product comprises a ganache filling optionally completed with one or more filling agents. Preferably the filling comprises between 70 and 100% by weight and preferably between 85 and 100% by weight of a ganache filling and between 0 and 30% by weight, preferably between 0 and 15% by weight of one or more filling agents, such as those defined above.

The term “ganache”, or “ganache filling”, as used herein, comprises essentially chocolate and cream and optionally other components such as sugars, vegetable fats, butter, oil and water. In a preferred embodiment the term “essentially” as used in this context refers to a ganache filling which contains more then 50% by weight, and preferably at least 70% by weight, and preferably at least 85% by weight, and preferably at least 90% by weight, and preferably at least 95% by of chocolate and cream.

In a preferred embodiment the present ganache filling comprises between 60 and 90% by weight, and preferably between 70 and 85% by weight of chocolate. The term “chocolate” as used herein is intended to refer to all chocolate or chocolate like compositions with a fat phase or fat-like composition. Definitions and standards for the various types of chocolate are well established. Non-standardized chocolates are those chocolates, which have compositions which fall outside the specified ranges of the standardized chocolates. The term chocolate is intended to include standardized and non-standardized chocolates, including dark (fondant) chocolate, baking chocolate, milk chocolate, sweet chocolate, semi-sweet chocolate, buttermilk chocolate, skimmilk chocolate, mixed dairy product chocolate, low fat chocolate, white chocolate, aerated chocolates, compound coatings, non-standardized chocolates and chocolate-like compositions, and any mixtures thereof. Chocolate also includes products containing crumb solids or solids fully or partially made by a crumb process. Non-standardized chocolates result when, for example, the nutritive carbohydrate sweetener is replaced partially or completely; or when the cocoa butter or milkfat are replaced partially or completely; or when components that have flavors that imitate milk, butter or chocolate are added or other additions or deletions in formula are made outside the standards of identity of chocolate or combinations thereof.

Dark (fondant), white or milk chocolate can be applied in a filling, and preferably a ganache filling, according to the present invention. A filling, and preferably a ganache filling according to the present invention, may also comprise mixtures of chocolate types. In an example the chocolate comprises a mixture of dark and milk chocolate in a ratio comprised between 5:1 and 1:5. In another example, the chocolate comprises a mixture of dark and white milk chocolate in a ratio comprised between 5:1 and 1:5. In yet another example, the chocolate comprises a mixture of milk and white chocolate in a ratio comprised between 5:1 and 1:5. In yet another example the chocolate comprises a mixture of dark/milk/white chocolate.

In a preferred embodiment, the ganache filling comprises between 10 and 40% by weight on the total weight of the ganache filling, and preferably between 15 and 30% by weight of cream.

In another preferred embodiment, the ganache filling comprises between 0 and 30% by weight on the total weight of the ganache filling, and preferably between 0 and 15% by weight of sugars. Suitable sugars may include but are not limited to glucose syrup, corn syrup, high fructose corn syrup, sucrose, dextrose, fructose, maltodextrin, glucose, tagatose, lactose, invert sugar, maltose, etc, . . . . Alternatively or in combination therewith also sugar alcohols selected from the group comprising but not limited to sorbitol, xylitol, lactitol, isomalt, maltitol, and the like or any mixtures thereof, may be applied in the present ganache filling, preferably at a concentration of between 0 and 30% by weight on the total weight of the ganache filling.

In another preferred embodiment, the ganache filling comprises between 0 and 30% by weight on the total weight of the ganache filling and preferably between 0 and 15% by weight of vegetable fats. Suitable vegetable fats may include but are not limited to palm, palm kernel or coconut fat, etc.

Furthermore, in another preferred embodiment, the ganache filling comprises between 0 and 30% by weight on the total weight of the ganache filling and preferably between 0 and 15% by weight of oils. Preferred oils include but are not limited to sunflower oil, olive oil, rapeseed oil, palm oil, etc.

In yet another preferred embodiment, the ganache filling comprises between 0 and 30% by weight on the total weight of the ganache filling and preferably between 0 and 15% by weight of butter.

In another preferred embodiment, the ganache filling comprises between 0 and 30% by weight on the total weight of the ganache filling, and preferably between 0 and 15% by weight of water.

In a preferred embodiment, the chocolate product comprises a ganache filling in which the ratio of chocolate to cream is comprised between 4:1 and 1:4 and for instance between 3:1 and 1:3, and for instance is 1:1; 2:1 or 3:1. In yet another preferred embodiment, the chocolate product comprises a ganache filling wherein the ratio of chocolate to sugars is comprised between 30:1 en 15:1, and for instance comprises 25:1. In another preferred embodiment, the chocolate product consists of a ganache filling wherein the ratio of chocolate to butter is comprised between 12:1 and 5:1, and for instance comprises 10:1. In yet another preferred embodiment, the chocolate product comprises a ganache filling wherein the ratio of chocolate to vegetable fats is comprised between is comprised between 12:1 and 5:1, and for instance comprises 10:1. In another preferred embodiment, the chocolate product comprises a ganache filling wherein the ratio of chocolate to oil is comprised between is comprised between 12:1 and 5:1, and for instance comprises 10:1.

In a preferred embodiment, the present invention relates to a device wherein the filling comprises chocolate and cream, and optionally a filling agent. Preferably the filling comprises between 60 and 90% by weight, and preferably between 70 and 85% by weight of chocolate; between 10 and 40% by weight, and preferably between 15 and 30% by weight of cream; and between 0 and 30% by weight, and preferably between 0 and 15% by weight of filling agents.

The jacket serves to conveniently encase the chocolate filling of the product. The jacket of the chocolate product ensures beside consistency also an improvement of the preservation circumstances whereby it offers protection to the filling and prevents desiccation and discoloration. The jacket serves as a protective barrier against the absorption of atmospheric moisture, which can lead to product spoilage.

The jacket comprises at least 70% by weight, preferably at least 80% by weight, preferably at least 90% by weight, preferably at least 95% by weight of chocolate. The chocolate may be a chocolate as defined above. It shall be apparent that this jacket may consist of different colors, which may indicate the taste of the chocolate milk that, may be expected. The jacket may consist of chocolate which has been covered with filling agents, such as for instance but not limited to nuts and the like.

The maximal thickness of the jacket is preferably 25% of the total thickness of the chocolate product whereby it is desired to keep the thickness of the jacket as small as possible because the melting behavior of the jacket is not optimal or takes more time. The thickness of the jacket is preferably as small as possible to ensure complete dissolution of the device. Suitable thicknesses may be of the range of 1 to 4 mm (+ or −1 mm).

The chocolate product according to the invention is provided on an agitator. The chocolate product has a preferred weight of between 10 and 40 gram and preferably of between 25 and 35 gram, and even more preferred of about 30 gram. In an example, the filling may have a weight comprised between 23 and 29 gram and the jacket may have a weight comprised between 5 and 8 gram.

The complete device, including agitator and chocolate product may take any possible configuration.

In a particular embodiment, also the chocolate product may take any possible configuration. In one embodiment, the basis of the chocolate product is smaller that its top. In another preferred embodiment, the basis of the chocolate product is larger that its top. In a preferred embodiment, the invention provides a device wherein the chocolate product is trapezoidal in transversal section. It is advantageous from a production point of view that the chocolate product is trapezoidal in transversal section. There are different production methods to produce this kind of devices, however a trapezoidal form improves the removal of the products out of production matrices. It shall however be clear that the chocolate product may have other configurations in transversal section. In another embodiment, for example, the width of the basis and of the top of the chocolate product may be equal. For instance, the chocolate product may be square or rectangular in transversal section or for instance, the chocolate product may be square or rectangular or circular or triangular in cross section. The chocolate product may be further provided with a relief that is preferably applied at the lower side of the product. The relief may for instance represent publicity, information, a logo or the like.

In a preferred embodiment, the invention provides a device wherein the chocolate product has a width which is at most 40 mm, and preferably at most 30 mm and more preferably at most 25 mm. in yet another embodiment, the invention provides a device wherein the chocolate product has an axial length which is at most 40 mm, and preferably at most 30 mm and more preferably at most 25 mm.

In another preferred embodiment the present invention may consist of an artisanal device for preparing hot chocolate milk. This artisanal device comprises an agitator having a chocolate product attached thereto, which has an essentially amorphous configuration. The chocolate product is preferably applied on the agitator by dipping. By the obtained amorphous form the surface of the chocolate product on the agitator is increased, which improves its melting behavior in milk.

The agitator used to carry out certain preferred embodiments of the present invention is preferably elongate in shape and is sufficiently rigid to support the chocolate product and to provide a means to agitate or stir the chocolate milk to mix ingredients therein. The agitator may comprise any suitable, substantially rigid, material. The agitator may be solid or hollow and may be of any suitable form such that it may be held by the handle region while the chocolate product is immersed in the hot milk. For example the support may comprise a sheet, a rod, a stick, a straw, a paddle or a tube. The agitator may be circular, square, triangular or rectangular and is suitable as carrier for information or publicity. The length of the agitator may vary between 5 and 30 cm, and preferably comprises between 10 and 15 cm, depending of the size of the cup, goblet or the glass wherein milk is provided and wherein one applies the agitator.

The agitator may be made of wood, metal, a synthetic material, bamboo, paper, carton or other materials. In another embodiment, the agitator may be made of an edible material. Preferably the agitator comprises a synthetic material, more preferably the agitator comprises a thermally stable synthetic material. It will be clear that this agitator may also comprise different colors, whereby the color may provide an indication of the taste, which can be expected for the chocolate milk.

It will further be clear that the adhesion surface of the agitator to the chocolate product is to be chosen as to provide sufficient grip to the chocolate and the filling. The agitator may include projections which can assist in retaining the chocolate product and possibly protecting the chocolate product from being knocked off. In a preferred embodiment, the agitator is therefore provided with surface enhancing means, such as but not limited to apertures, recesses, teeth, scales, ribs, ridges, projections, fins or the like, for improving adherence of the chocolate product.

The chocolate product is preferably provided at the end of the agitator. Optionally, the chocolate product may be provided in the middle of the agitator such that the length of the trajectory of the dissolved chocolate product to the bottom is increased. However, having regard to the application of the product, it is easier to provide the chocolate product at the end of the agitator. In a preferred embodiment the chocolate product is in a preformed shape such as a cube, trapezium, cylinder, or other shapes, which preformed shape may be substantially axially aligned with the agitator.

In another embodiment, the chocolate product is attached to more than one agitator.

The agitator may be connected to the chocolate product by any suitable means but is preferably connected by dipping the agitator in the filling, after which the chocolate filling is coated with the chocolate jacket. More in particular, the present device is prepared as follows. In a first step the chocolate filling as described herein is prepared by mixing the required ingredients as defined herein. Then the filling is encased or molded by transferring it to a suitable mould, and allowed to at least partly solidify for a suitable period of time, for instance 20 to 24 hours at room temperature. Subsequently, the solidified chocolate filling is cut to a desired shape and an agitator is dipped in the solidified filling. In a further step, the filing is coated with a chocolate jacket. During the coating process, also a small axial length of the agitator is coated with the jacket, to ensure proper protection and hygienic coverage of the filling at the site of entry of the agitator in the product.

In another preferred embodiment the present device is provided in a packing, by preference an air-tight packing.

In addition, the chocolate product on the present device may be further provided with a wrapper that is adapted for at least partly wrapping the chocolate product. The term “at least partly” as used herein indicates that a part of the chocolate product according to the present invention remains uncovered and thus visible. Preferably the wrapper is adapted to cover the upper and lower side of the chocolate product and two of its lateral sides. By covering two of the lateral sides of the product, the wrapper is particularly suitable for enabling a user to pick up and hygienically hold the device according to the present invention by the chocolate product without touching the chocolate product.

In one embodiment, the wrapper is removed from the device prior to use. More in particular, the chocolate product is provided with a wrapper that has been loosely folded around the chocolate product and that is adapted to facilitate sanitary removal of the wrapper immediately prior to use. It can be easily removed by a user. The wrapper may comprise any material well known in the food industry for wrapping food products. The wrapper is in particular adapted such that the chocolate product does not stick to it. For example the wrapper may comprise a synthetic material such as e.g. cellophane, saran or other plastic film, bamboo, paper, a waxed paper material, carton or other materials.

In an alternative embodiment, the wrapper is not removed from the device prior to use. In such embodiment, the wrapper may comprise an insoluble layer of material that is perforated or porous. The perforations may be of a suitable size such that only dissolved chocolate product or small particles of the chocolate product may pass through and be released into the milk upon the insertion into milk. The wrapper may for instance comprise a perforated plastic material especially a thermally stable plastics material. Upon insertion of the applicator into the milk the chocolate product dissolves and the solution passes through perforations in the wrapper. This embodiment has the advantage that the chocolate product is retained within the wrapper until it is dissolved, or in the form of small particles and so lumps of undissolved chocolate product may be completely avoided in the milk.

In yet another embodiment, the wrapper for the chocolate product may be edible and may for instance comprise gelatin, or edible paper.

Preferably the wrapping may also comprise different colors, whereby the color may provide an indication of the taste, which can be expected for the chocolate milk. The wrapper may also serve as a carrier for information, publicity or the like.

Preferably the present device may have a shelf life of about 3 to 6 months in a relatively dry, e.g. relative humidity below 70%; cool, e.g. below 30° C.; and odorless environment.

In use, the chocolate product of the present invention is placed in a hot beverage, preferably milk, as described above and agitated therein, such as by stirring, until the chocolate product including coating and chocolate filling is dispersed therein. By “dispersed” is meant that chocolate product is substantially uniformly distributed within the liquid by dissolution, suspension, etc. . . . , and no longer exists as a discrete physical entity. Agitation is meant ordinary hand agitation and is typically carried out by stirring. Preferably chocolate product will fully disperse within 50 seconds, and preferably within 30 seconds from the onset of agitation in milk having a temperature comprised between 70 and 90° C. Agitation or stirring may be carried out with an agitator formed onto or connected to the chocolate product as described herein, or by agitation with a spoon, stirrer or the like.

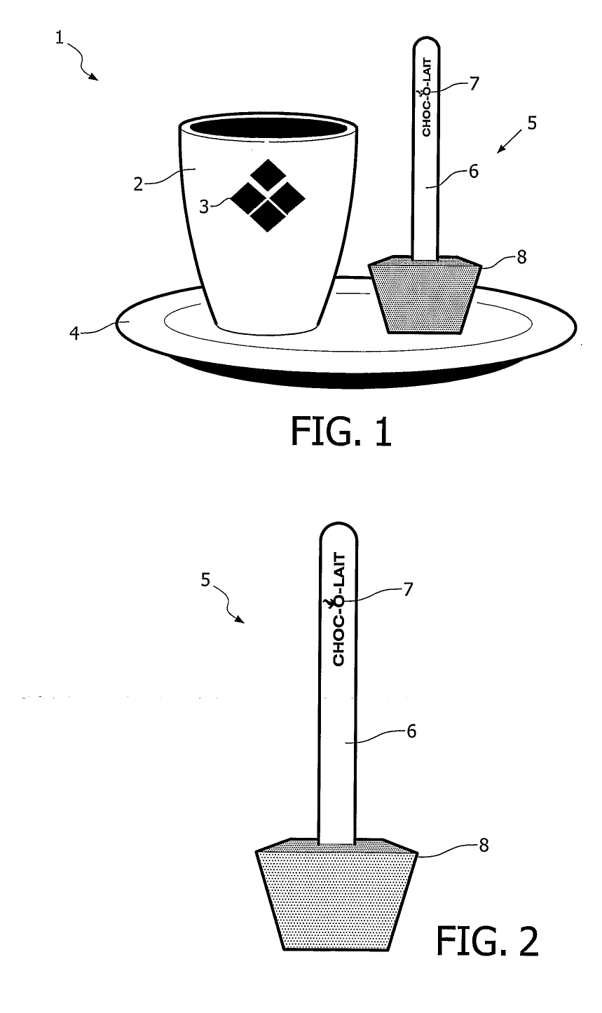

In reference to the figures, it will be clear that FIG. 1 describes a kit 1 provided with a cup 2 and a device 5 according to the invention, which are both placed on a common dish 4.

A device 5, also named choco-stick, according to the present invention, is further represented in FIG. 2 and comprises an agitator 6, which is partly immersed in the chocolate product 8 such that sufficient firmness is provided to admit the device in hot milk that is present in cup 2. In addition, the agitator 6 is provided with a publicity message or a logo 7. It will be clear that the part of the agitator inside the chocolate product that is not represented also can be provided with other surface enhancing means in order to improve attachment of the chocolate product. The cup 2 of the kit 1 may be provided with a sign or logo 3. As represented on the figures, the chocolate product is of a trapezoidal form in transversal section. This trapezoidal form facilitates the release of the chocolate product from a mould during the production process.

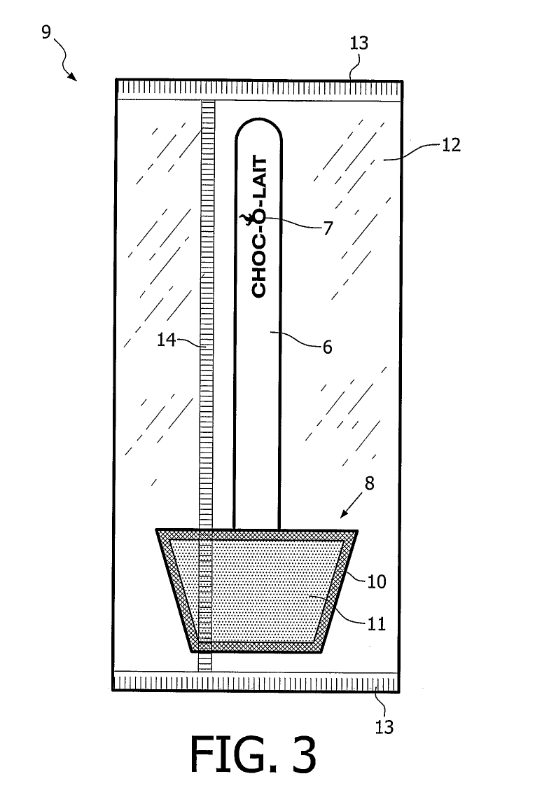

In a preferred embodiment of the device, as represented in FIG. 3, an individual packing 9 for packing the device 5 according to the invention is provided, by preference this is an air-tight packing, for instance a flow pack provided with seals 13 and 14. Optionally, the surface 12 of the individual packing may also be used as carrier for publicity or information or logo 7. The chocolate product preferably consists of an external chocolate jacket 10 and an internal layer 11, comprising a dissoluble filling of chocolate, cream and/or oil, optionally provided with other further filling products as defined herein.

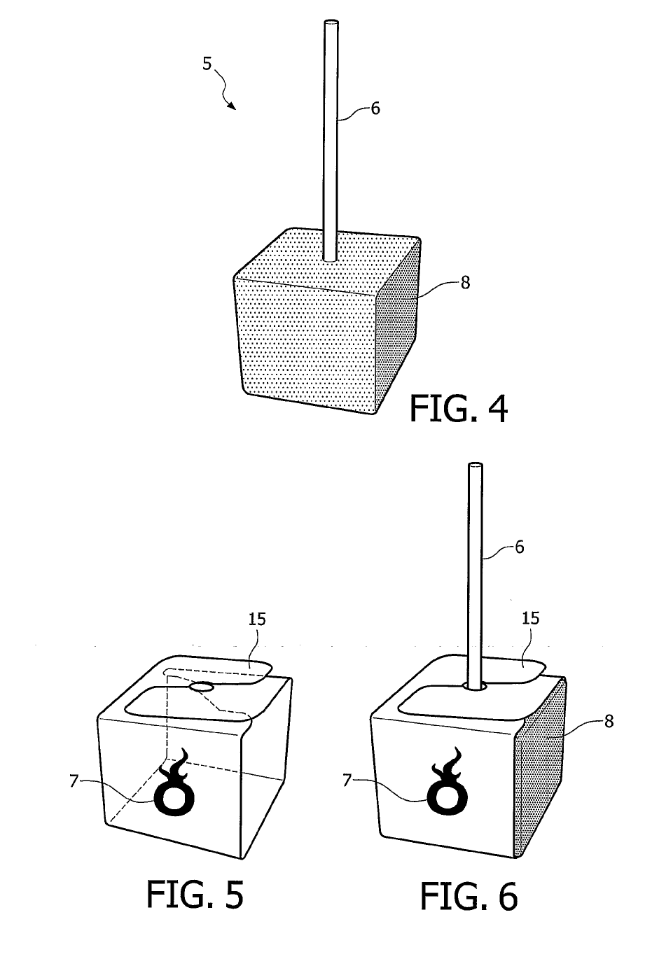

FIG. 4 represents a device 5 according to the present invention is represented wherein the chocolate product 8 is of a square form in transversal section. FIG. 5 illustrates a wrapper 15 that is adapted for at least partly wrapping the chocolate product of a device according to the invention. FIG. 6 represents a preferred embodiment of device 5 according to the present invention, wherein the device has been wrapped with a wrapper 15 as represented in FIG. 5 which partly wraps the chocolate product. The wrapper is adapted to wrap the upper and lower side of the chocolate product and two lateral sides of the product. The two other lateral sides of the product remain visible for a consumer. The individual wrapper may also be used as carrier for publicity or information or logo 7.

In the following table 1 some examples of compositions a filling of a chocolate product according to the present invention are provided.

TABLE 1

| | composition 1 | composition 2 | composition 3 |
|---|---|---|---|
| filling | (% by weight) | (% by weight) | (% by weight) |
| chocolate | 75 | 70 | 70 |
| cream | 25 | 30 | 20 |
| filling agents | — | — | 10 |
| (e.g. cointreau) | | | |

In another example, a filling according to the present invention comprises 210 gram of a hazelnut paste, 125 gram of chocolate and 105 gram of cream.

What is claimed is:

1.-15. (canceled)

16. A method for manufacturing a thin-layer structure, comprising:
a macroporous supporting structure substrate having a plurality of pores that do not pass through the entire thickness of the substrate layer;
applying a sacrificial layer on a surface of the pore walls and the pore bottoms of the supporting structure substrate;
partly removing the supporting structure substrate on the rear side, such that a region of the sacrificial layer is uncovered on the rear side of the supporting structure substrate;
applying a thin layer on the rear side surface of the supporting structure substrate and also on the uncovered region of the sacrificial layer; and
removing the sacrificial layer in the pores selectively with respect to the thin layer, such that the pore bottoms are formed by the thin layer.

17. The method of claim 16, comprising forming the sacrificial layer by thermal oxidation of the pore walls and of the pore bottoms.

18. The method of claim 16, comprising applying the sacrificial layer to the pore walls and pore bottoms of the supporting structure substrate by a chemical vapor deposition method.

19. The method of claim 18, comprising applying the sacrificial layer to the pore walls and pore bottoms of the supporting structure substrate by an atomic layer epitaxy method.

20. The method of claim 16, comprising manufacturing the supporting structure substrate from silicon material.

21. The method of claim 20, comprising:
applying a silicon dioxide layer as sacrificial layer; and
applying a silicon dioxide layer to the pore walls and pore bottoms of the supporting structure substrate by thermal oxidation.

22. The method of claim 20, comprising:
applying a silicon nitride layer as sacrificial layer; and
applying a silicon nitride layer to the pore walls and pore bottoms of the supporting structure substrate in particular by means of a thermal CVD method.

23. The method of claim 16, comprising producing the supporting structure substrate from Al material.

24. The method of claim 23, comprising wherein the sacrificial layer is an aluminum oxide layer applied to the pore walls and pore bottoms of the supporting structure substrate by an ALD method.

25. The method of claim 16, comprising performing the partial removal of the supporting structure substrate on the rear side using an etching-back method.

26. The method of claim 16, comprising applying the thin layer by a sputtering method or a vapor deposition method or a plasma CVD method.

27. The method of claim 26, comprising applying a diamond thin layer as the thin layer.

28. The method of claim 26, comprising applying a metal thin layer as the thin layer.

29. The method of claim 16, comprising applying the layer sequence having a plurality of partial thin layers as the thin layer.

30. The method of claim 16, comprising selectively removing the sacrificial layer by etching.

31. A method for manufacturing a wafer having a thin-layer structure, comprising:
a macroporous supporting structure substrate having a plurality of pores that do not pass through the entire thickness of the substrate layer;
applying a sacrificial layer on the surface of the pore walls and the pore bottoms of the supporting structure substrate; and
partly removing the supporting structure substrate on the rear side, such that a region of the sacrificial layer is uncovered on the rear side of the supporting structure substrate.

32. The method of claim 31, comprising:
applying a thin layer on the rear side surface of the supporting structure substrate and also on the uncovered region of the sacrificial layer.

33. The method of claim 32, comprising:
removing the sacrificial layer in the pores selectively with respect to the thin layer, such that the pore bottoms are formed by the thin layer.

34. The method of claim 31, comprising forming the sacrificial layer by thermal oxidation of the pore walls and of the pore bottoms.

35. The method of claim 31, comprising manufacturing the supporting structure substrate from silicon material.

36. The method of claim 31, comprising:
applying a silicon dioxide layer as sacrificial layer; and
applying a silicon dioxide layer to the pore walls and pore bottoms of the supporting structure substrate by thermal oxidation.

37. The method of claim 31, comprising:
applying a silicon nitride layer as sacrificial layer; and
applying a silicon nitride layer to the pore walls and pore bottoms of the supporting structure substrate in particular by means of a thermal CVD method.
